(19) United States
(12) Patent Application Publication
(10) Pub. No.: US 2024/0038607 A1
(43) Pub. Date: Feb. 1, 2024

(54) INTEGRATED CIRCUIT PACKAGE

(71) Applicant: STMicroelectronics (Grenoble 2) SAS, Grenoble (FR)

(72) Inventors: Fanny LAPORTE, Villaz (FR); David AUCHERE, Meylan (FR)

(73) Assignee: STMicroelectronics (Grenoble 2) SAS, Grenoble (FR)

(21) Appl. No.: 18/226,409

(22) Filed: Jul. 26, 2023

(30) Foreign Application Priority Data
Aug. 1, 2022 (FR) 2207955

(51) Int. Cl. H01L 23/13; H01L 25/16; H01L 23/00; H01L 21/306

(52) U.S. Cl. CPC H01L 23/13; H01L 25/165; H01L 24/16; H01L 24/32; H01L 24/73; H01L 21/306; H01L 2224/16225; H01L 2224/32225; H01L 2224/73204; H01L 2224/73253; H01L 2924/15151; H01L 2924/16151; H01L 2924/1616; H01L 2924/16251; H01L 2924/16235

(57) ABSTRACT

An integrated circuit package includes a cavity within which a circuit device is contained. At least one through hole is provided in at least one wall of the cavity. The at least one through hole includes at least one first portion flaring towards the cavity with a frustoconical shape, for example.

### PRIORITY CLAIM

This application claims the priority benefit of French Application for Patent No. 2207955, filed on Aug. 1, 2022, the content of which is hereby incorporated by reference in its entirety to the maximum extent allowable by law.

### TECHNICAL FIELD

Embodiments and implementations relate to integrated circuit packages, whether they are optical or not, and especially relate to integrated circuit packages equipped with at least one cavity generally for housing one or more electronic components, for example but not limited to, electronic integrated circuit chips, surface-mount components, optical components, etc.

### BACKGROUND

Currently, the cavities provided in integrated circuit packages require one or more ventilation holes in order to ensure reliability of these packages.

Indeed, the absence of a ventilation hole can lead to overpressure and delamination of some materials of the package during the manufacture of the package, leading to operating problems.

But the flow of operations for assembling a package includes, especially, sawing and cleaning operations.

As a result, water can enter the package, leading to pollution of the cavity, degradation of optical performance (in the case of optical packages), condensation, oxidation of components and reliability problems.

There is therefore a need to provide packages having cavities that can be equipped with ventilation holes while limiting ingress of external pollution (water and liquids, particles, etc.) into these cavities as much as possible.

### SUMMARY

According to one aspect, an integrated circuit package is provided comprising a cavity and at least one through hole, provided in at least one wall of the cavity, said at least one through hole comprising at least one first portion flaring towards the cavity.

As a result, the capillary force becomes negligible due to the flaring effect of the first portion, in relation to the force of gravity, which greatly reduces or even eliminates the risk of external pollution, in particular moisture, penetrating the cavity.

In general, the package may typically comprise a carrier substrate and a device attached to the carrier substrate and delimiting said cavity with the carrier substrate.

This device may be, for example, a cover, an optical sealing means (for example, a glass pane), or even a molded element.

Said wall includes a part of the carrier substrate and a part of the device. And, said at least one through hole may be provided in said part of the carrier substrate and/or said part of the device.

Said at least one first portion flares from a first end to a second end. And, in order to further promote flaring effect to make the capillary force negligible, the cross-section of said at least one first portion at the first end has a largest dimension less than or equal to 35 micrometers.

Said at least one first portion may be frustoconical.

According to one embodiment, said at least one first portion extends over the entire thickness of said at least one wall.

This is, for example, the case for relatively thin carrier substrates.

For relatively thick carrier substrates, said at least one through hole may include at least one second portion opening into said at least one first portion at the end of this first portion having the smallest cross-section.

This second portion may be cylindrical or may flare away from said at least one first portion.

According to one embodiment, said at least one second portion may be frustoconical and said at least one through hole then includes the first portion and the second portion connected by their respective ends having the smallest cross-section.

According to another aspect, a method is provided for making at least one through hole in at least one wall of a cavity of an integrated circuit package, making said at least one through hole comprising making at least one first portion flaring towards the cavity.

According to one implementation wherein the package comprises a carrier substrate and a device attached to the carrier substrate and delimiting said cavity with the carrier substrate, said wall including a part of the carrier substrate and a part of the device, said at least one through hole is made in said part of the carrier substrate and/or in said part of the device.

According to one implementation, said at least one first portion is made so that it flares from a first end to a second end, the cross-section of said at least one first portion at the first end having a largest dimension less than or equal to 35 micrometeres.

According to one implementation, said at least one first portion is made with a frustoconical shape.

According to one implementation, said at least one first portion is made so that it extends over the entire thickness of said at least one wall.

Making said at least one first portion advantageously comprises laser drilling.

Indeed, laser drilling naturally provides a flared shape to the port drilled.

According to one implementation, making said at least one through hole includes making at least one second portion opening into said at least one first portion at its end having the smallest cross-section.

Said at least one second portion may be made so that it has a cylindrical shape.

In this case, making said at least one second portion advantageously comprises mechanical drilling.

Said at least one second portion may also be made so that it flares away from said at least one first portion.

In this case, said at least one second portion is advantageously performed by means of laser drilling.

According to one implementation, making said at least one through hole comprises making said at least one second portion having a frustoconical shape, and making the first portion and the second portion so that they are connected by their respective ends having the smallest cross-section.

### BRIEF DESCRIPTION OF THE DRAWINGS

Further advantages and characteristics of the invention will become apparent upon examining the detailed description of embodiments and implementations, which are by no means limiting, and the appended drawings in which:

FIG. 1 shows an integrated circuit package in cross section;

FIG. 2 shows details of a through hole provided extending in and completely though an entire thickness of a part of a carrier substrate for the package of FIG. 1;

FIGS. 3-4 show details of another embodiment for the through hole provided extending in and completely though an entire thickness of a part of a carrier substrate for the package;

FIG. 5 shows an optical integrated circuit package in cross section; and

FIG. 6 shows details of another embodiment where the through hole is provided to extend in and completely though an entire thickness of a cover for the package.

### DETAILED DESCRIPTION

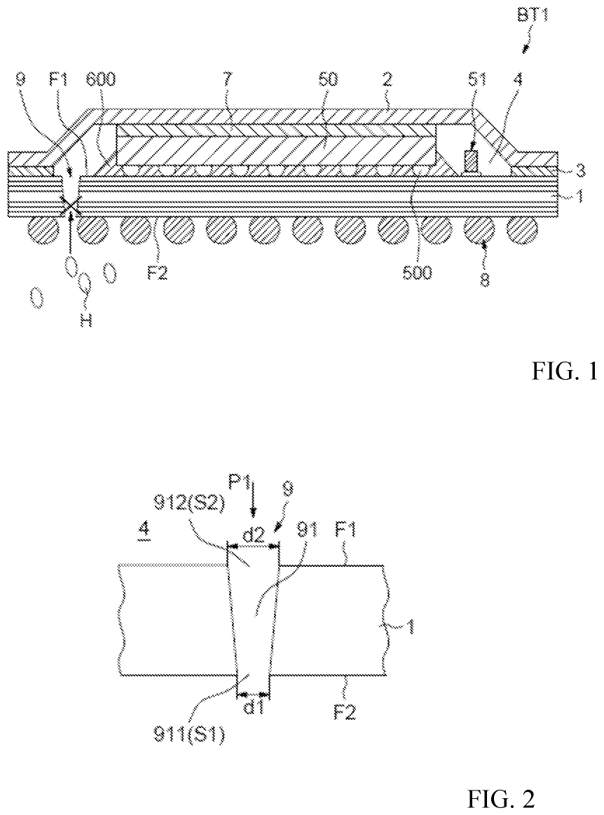

In FIG. 1, reference BT1 refers to an integrated circuit package shown in cross section.

This integrated circuit package comprises a carrier substrate 1, for example a conventional multilayer carrier substrate, including a first face F1, typically an upper face, and a second face F2, typically a lower face.

The second face F2 is here equipped with an array of solder balls 8 for being soldered to a printed circuit board.

A cover 2 is attached to the first face F1 of the carrier substrate 1 by means of a conventional attachment means 3 such as an adhesive material.

A part of the carrier substrate 1 and a part of the cover 2 delimit a cavity 4 in which, an electronic integrated circuit chip 50 and an electronic component 51, for example a surface-mount component, are housed, in this exemplary embodiment.

The electronic chip 50 rests on the first face F1 of the substrate via connection balls or bumps 500.

An underfill material 600 is disposed between the electronic chip 50 and the first face F1 of the substrate.

In this example, a thermal interface material 7 is disposed between the upper face of the chip 50 and the cover 2 so as to promote thermal dissipation of the package.

In this exemplary embodiment, a through hole 9 is provided extending in and completely though the entire thickness of a part of the carrier substrate and flares (for example, increases in size) towards the cavity 4.

As a result, the risk of moisture H penetrating the cavity is greatly reduced or eliminated.

As illustrated in more detail in FIG. 2, the through hole 9 is formed in this embodiment by a first portion 91 having a first end 911 opening at the second face F2 of the carrier substrate, and a second end 912 opening into the cavity 4 at the first face Fl of the carrier substrate.

The first portion 91 may be frustoconical.

The cross-section S1 of the first portion 91 at the first end 911 is then, for example, a circular cross-section, the largest dimension, or diameter, d1 of which is advantageously less than or equal to 35 microns.

The second end 912 of the first portion 91 has a cross-section S2, also circular, the largest dimension, or diameter, d2 of which may be, for example, in the order of 100 microns.

As a result, the capillary force becomes negligible in relation to, for example, the force of gravity, due to the conical effect and the opening size of the first end 911.

Such an embodiment, providing a first portion passing through the entire thickness of the carrier substrate is typically possible for relatively thin carrier substrates, that is having for example a thickness less than or equal to 1000 μm.

This portion 91 can advantageously be made by laser drilling P1 which naturally provides a flared shape to the port drilled.

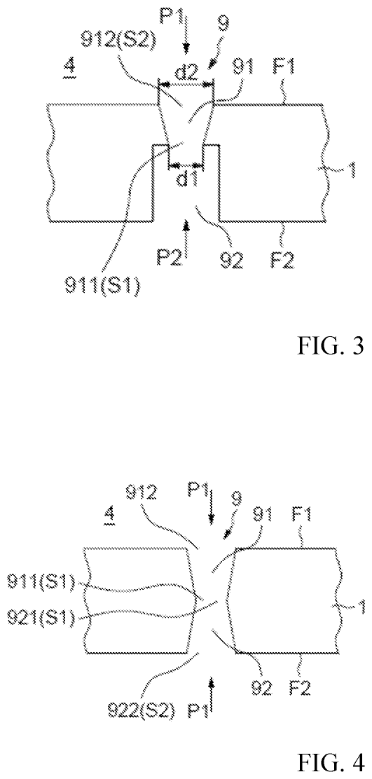

In the case of a thicker carrier substrate, having for example a thickness greater than or equal to 4000 μm, a through hole 9 can be provided, as very schematically illustrated in FIGS. 3 and 4, including the first flared portion 91 and a second portion 92 opening into the first portion 91 at its first end 911 which has the smallest cross-section 51.

In FIG. 3, the second portion 92 may be a cylindrical portion having, for example, a diameter of between 150 and 200 microns while the diameter d1 is less than or equal to 35 microns.

In this embodiment, any moisture that may have penetrated the second portion 92 gets stuck at the first portion 91.

While the first portion 91 is advantageously made by laser drilling P1, the second portion 92 can be made by mechanical drilling P2.

In one embodiment of FIG. 4, the second portion 92 flares away from the first portion 91.

More precisely, the second portion 92 has a first end 921 which is coincident with the first end 911 of the first portion.

The second portion 92 has a second end 922 opening onto the second face F2 of the carrier substrate.

The cross-section S2 of this second end 922 is larger than the cross-section Si of the first end 921.

The two portions 91 and 92 may thus be frustoconical, the two frustoconical parts 91 and 92 being mutually connected at their respective ends 911 and 921 having the smallest cross-section S1.

In this embodiment, the two frustoconical portions 91 and 92 can be advantageously made by laser drilling P1.

Here again, any moisture H which would have penetrated the second portion 92 will be stopped from penetrating through the first frustoconical portion 91.

The invention is not limited to the embodiments and implementations described here, but encompasses all alternatives.

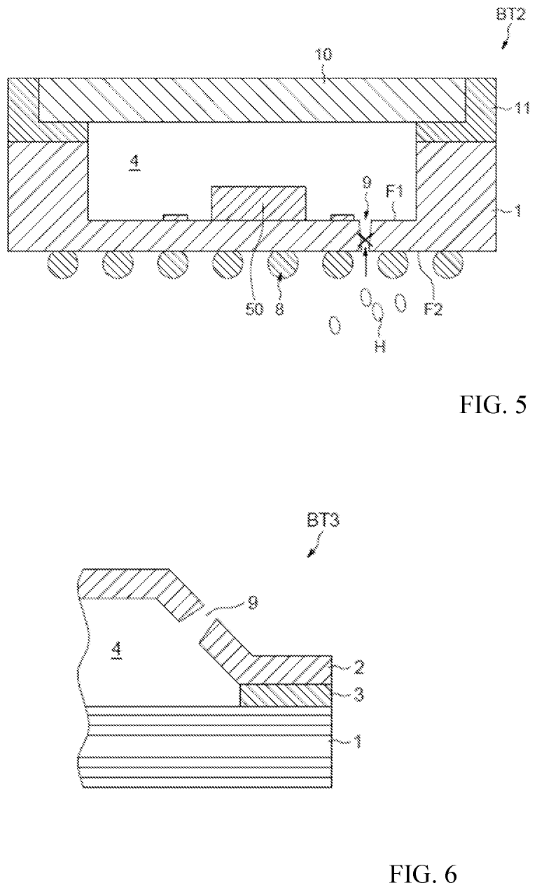

Thus, the invention can be applied to all types of packages, in particular an optical package BT2 such as that schematically illustrated in FIG. 5.

This optical package BT2 includes a carrier substrate 1 equipped on its second face F2 with an array of connection balls 8. An optical sealing element 10, for example a glass pane, is attached to the carrier substrate 1 by means of a conventional attachment means 11 such as an adhesive material and defines, together with the carrier substrate, the cavity 4 which houses in this example an optical component 50.

Here again, a through hole 9 flaring towards the cavity 4 from the second face F2 of the carrier substrate limits or even eliminates the risk of moisture H penetrating the cavity 4.

Whereas in the embodiments of FIGS. 1 and 5, the through hole was provided in the carrier substrate, it could also be provided, as very schematically illustrated in FIG. 6, in the device delimiting said cavity with the carrier substrate.

In the present case, this device is the cover 2 in FIG. 6 and the through hole 9 can be provided in this cover 2 so that it flares towards the cavity 4.

1. An integrated circuit package, comprising:
a carrier substrate;
a circuit device attached to the carrier substrate; and
a package cover mounted to the carrier substrate and delimiting a cavity within which the circuit device is contained;
wherein the carrier substrate includes at least one through hole provided to extend completely through the carrier substrate to reach said cavity; and
wherein said at least one through hole includes at least one first portion flaring towards the cavity.

2. The package according to claim 1, wherein said at least one first portion flares from a first end located at a bottom of the carrier substrate to a second end located at said cavity, and wherein a cross-section of said at least one first portion at the first end has a largest dimension that is less than or equal to 35 micrometers.

3. The package according to claim 1, wherein said at least one first portion is frustoconical.

4. The package according to claim 1, wherein said at least one first portion extends over an entire thickness of said carrier substrate.

5. The package according to claim 1, wherein said at least one through hole further includes at least one second portion that is connected to said at least one first portion.

6. The package according to claim 5, wherein the connection of said at least one first portion and at least one second portion extends over an entire thickness of said carrier substrate.

7. The package according to claim 5, wherein said at least one second portion is cylindrical.

8. The package according to claim 5, wherein said at least one second portion flares in an opposite direction from said at least one first portion.

9. The package according to claim 5, wherein said at least one first portion is 15 frustoconical, and wherein said at least one second portion is frustoconical, and wherein the at least one through hole formed by the at least one first portion and the at least one second portion has the at least one first portion and the at least one second portion connected by respective ends having smaller cross-sections.

10. The package according to claim 9, wherein said smaller cross-sections at the ends are each less than or equal to 35 micrometers.

11. A method, comprising:
forming at least one through hole extending completely through a carrier substrate;
mounting a circuit device to the carrier substrate; and
mounting a package cover to the carrier substrate to delimiting a cavity within which the circuit device is contained;
wherein said at least one through hole opens into the cavity; and
wherein said at least one through hole includes at least one first portion flaring towards the cavity.

12. The method according to claim 11, wherein said at least one first portion flares from a first end located at a bottom of the carrier substrate to a second end located at said cavity, and wherein a cross-section of said at least one first portion at the first end has a largest dimension that is less than or equal to 35 micrometers.

13. The method according to claim 11, wherein said at least one first portion is frustoconical.

14. The method according to claim 11, wherein said at least one first portion extends over an entire thickness of said carrier substrate.

15. The method according to claim 11, wherein said at least one through hole further includes at least one second portion that is connected to said at least one first portion.

16. The method according to claim 15, wherein the connection of said at least one first portion and at least one second portion extends over an entire thickness of said carrier substrate.

17. The method according to claim 15, wherein said at least one second portion is cylindrical.

18. The method according to claim 17, further comprising forming said at least one second portion by mechanical drilling.

19. The method according to claim 15, wherein said at least one second portion flares in an opposite direction from said at least one first portion.

20. The method according to claim 15, wherein said at least one first portion is 15 frustoconical, and wherein said at least one second portion is frustoconical, and wherein the at least one through hole formed by the at least one first portion and the at least one second portion has the at least one first portion and the at least one second portion connected by respective ends having smaller cross-sections.

21. The method according to claim 20, wherein said smaller cross-sections at the ends are each less than or equal to 35 micrometers.

22. The method according to claim 20, wherein making each of said at least one first portion and said at least one second portion comprises performing a laser drilling.

23. The method according to claim 11, wherein forming at least one through hole comprises performing a laser drilling.
